(19) United States
(12) Patent Application Publication
(10) Pub. No.: US 2026/0314349 A1
(43) Pub. Date: Oct. 8, 2026

(54) METHOD FOR FORMING THROUGH WAFER VIA

(71) Applicant: SKYWORKS SOLUTIONS, INC., Irvine, CA (US)

(72) Inventor: Kezia Cheng, Lowell, MA (US)

(21) Appl. No.: 19/405,645

(22) Filed: Dec. 2, 2025

Related U.S. Application Data
(60) Provisional application No. 63/728,340, filed on Dec. 5, 2024.

(51) Int. Cl. H10W 20/00

(52) U.S. Cl. CPC H10W 20/0261; H10W 20/0234

(57) ABSTRACT

Disclosed herein is a method of forming a through wafer via in a substrate. The method comprises defining an aperture in the substrate, the aperture defining one of a through hole passing entirely through the substrate from a front side of the substrate to a rear side of the substrate or a blind hole terminating on a metal pad disposed on the rear side of the substrate, depositing a copper paste within the aperture, and sintering the copper paste.

### CROSS-REFERENCE TO RELATED APPLICATIONS

This application claims priority under 35 U.S.C. §119(e) to U.S. Provisional Patent Application Ser. No. 63/728,340 titled “METHOD FOR FORMING THROUGH WAFER VIA,” filed Dec. 5, 2024, the entire content of which is incorporated herein by reference for all purposes.

### BACKGROUND

### Technical Field

Embodiments disclosed herein relate to methods of forming through wafer vias (TWVs).

### Description of Related Technology

Various semiconductor manufacturing processes make use of through wafer vias (TWVs) to provide electrical connections between devices formed on the front side of a semiconductor substrate and electrical contacts on the rear side of the semiconductor substrate. For example, in some processes of fabricating microchips including heterojunction bipolar transistors or high electron mobility transistors, TWVs may be utilized to provide a connection between devices and ground. As illustrated in FIG. 1 a conductive trace 15 may provide electrical communication between a device 10 formed on or in the front side of a substrate 5, for example, a semiconductor wafer to a TWV 20 formed in an aperture 25 defined in and passing through the substrate 5 to a rear side electrical contact 30.

### SUMMARY

In accordance with one aspect, there is provided a method of forming a through wafer via in a substrate. The method comprises defining an aperture in the substrate, the aperture defining one of a through hole passing entirely through the substrate from a front side of the substrate to a rear side of the substrate or a blind hole terminating on a metal pad disposed on the rear side of the substrate, depositing a copper paste within the aperture, and sintering the copper paste.

In some embodiments, defining the aperture in the substrate includes etching the substrate.

In some embodiments, defining the aperture in the substrate includes performing an anisotropic etch on the substrate.

In some embodiments, defining the aperture in the substrate includes performing an isotropic etch on the substrate.

In some embodiments, defining the aperture in the substrate includes plasma etching the substrate.

In some embodiments, defining the aperture in the substrate includes performing an ion milling operation on the substrate.

In some embodiments, the method further comprises disposing an etch stop layer on the rear side of the substrate prior to defining the aperture above the etch stop layer.

In some embodiments, depositing the copper paste within the aperture includes screen printing the copper paste into the aperture.

In some embodiments, screen printing the copper paste into the aperture includes partially filling the aperture with copper paste by screen printing a first layer of copper paste into the aperture.

In some embodiments, the method further comprises screen printing a second layer of the copper paste on top of the first layer of copper paste, the first and second layer of copper paste filling the aperture.

In some embodiments, the method further comprises removing an air pocket from the aperture below the first layer of copper paste.

In some embodiments, removing the air pocket includes exposing the rear side of the substrate to a vacuum.

In some embodiments, the method further comprises depositing an adhesion layer on walls of the aperture prior to depositing the copper paste within the aperture.

In some embodiments, the adhesion layer is deposited by sputtering.

### BRIEF DESCRIPTION OF THE DRAWINGS

Embodiments of this disclosure will now be described, by way of non-limiting example, with reference to the accompanying drawings.

FIG. 1 is a simplified cross-sectional view of a connection between a device on the front side of a substrate and an electrical contact on the rear side of the substrate using a through wafer via;

FIG. 2A-2G illustrates an act performed in a method of forming a copper TWV in a substrate as disclosed herein;

FIG. 2B illustrates another act performed in a method of forming a copper TWV in a substrate as disclosed herein;

FIG. 2C illustrates another act performed in a method of forming a copper TWV in a substrate as disclosed herein;

FIG. 2D illustrates another act performed in a method of forming a copper TWV in a substrate as disclosed herein;

FIG. 2E illustrates another act performed in a method of forming a copper TWV in a substrate as disclosed herein;

FIG. 2F illustrates another act performed in a method of forming a copper TWV in a substrate as disclosed herein;

FIG. 2G illustrates another act performed in a method of forming a copper TWV in a substrate as disclosed herein; and

FIG. 3 is a flowchart of acts performed in a method of forming a copper TWV in a substrate as disclosed herein

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Through wafer vias (TWVs) may be utilized in various types of microchips or other semiconductor devices to provide electrical connections between one side (e.g., the font side) of a substrate, for example, a semiconductor wafer, to the other side (e.g., the rear side) of the substrate. In some examples, the electrical connection is between a device such as a transistor formed on or in the front side of the substrate and an electrical contact, for example, a signal or ground contact on the rear side of the substrate. TWVs may also be used for redistribution connection contacts in wafer level packaging of other devices, for example, devices including bulk acoustic wave and surface acoustic wave filters.

A process for forming a TWV may include etching, milling, or drilling an aperture through a substrate, either as a through hole or as a blind hole, depositing a metal seed layer by, for example, sputtering, and then electroplating the substrate to deposit a metal via in the aperture passing from the front to the rear side of the substrate. TWVs may be formed from gold, copper, or any other suitable metal.

Current processes of forming TWVs by electroplating have some disadvantages. Conformally sputter coating high aspect ratio via apertures can be challenging. Forming a good quality metal sputter coating may involve operating a sputtering tool under low pressure and high power. The combination of sputtering under low pressure and high power can, however, result in high compressive film stress which may result in reliability issues, for example, delamination of the deposited film. Good plating coverage inside the via apertures, sometimes referred to as “throwing power,” may also necessitate frequent plating bath analysis, maintenance and replacement. Plating solution and replenishers, especially for gold via formation, are expensive. The plating process often has relatively low throughput, for example, taking about 30 minutes to electroplate one wafer. In some examples the via aperture may not be fully plated with the electroplated metal to a desired thickness, resulting in possible performance and/or reliability issues.

Aspects and embodiments disclosed herein include processes for forming copper TWVs that may avoid many of the disadvantages of prior electroplating-based processes. Aspects and embodiments disclosed herein may offer a low cost solution with increased throughput by using thick film technology to form completely filled TWVs. Aspects and embodiments disclosed herein may utilize screen printing techniques to form TWVs from metal paste instead of by sputtering and electroplating. Screen printing Cu paste into a TWV aperture can completely fill the TWV aperture with a thick Cu film, or at least more completely fill the TWV aperture than some electroplating-based processes. Because the TWVs are completely filled, better thermal and electrical conduction is observed. In embodiments in which the TWVs are used to provide ground connections to devices operating at radio frequencies (RF), the low impedance to ground improves RF performance. Screen printing is low cost with high throughput and low maintenance. In contrast, plating processes utilize expensive plating tools with analytical instruments to support the process and require a lot of engineering time to maintain.

Copper thick film pastes that cure and sinter at low temperatures are now available. The thick film pastes are screen printable. Commercially available examples include the Cu pastes available from the Resonac Holdings Corporation. Aspects and embodiments disclosed herein employ thick film technology to completely fill TWVs instead of forming the TWVs by electroplating. In some embodiments, Cu thick film paste is applied on the wafer through a screen print mask or, alternatively, directly onto the surface of a substrate without the use of a mask. The Cu paste may not completely fill the via apertures on the first pass. A vacuum step may be utilized to remove air pockets trapped in the vias. A second pass with the screen printer fully fills the via apertures with the Cu paste. The wafers in which the Cu paste TWVs are formed may then be sintered to cure the Cu paste into solid copper TWVs. Sintering may be performed at temperatures of between about 120° C. and about 300° C., for example, about 200° C.

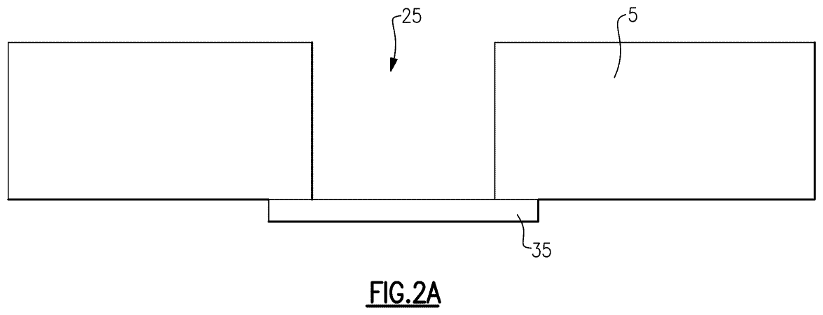

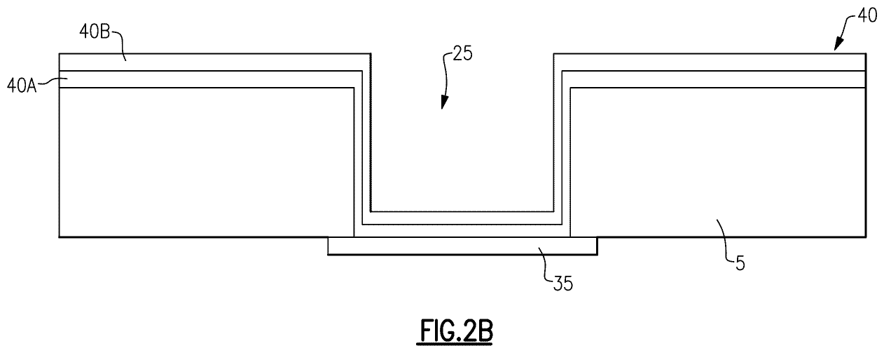

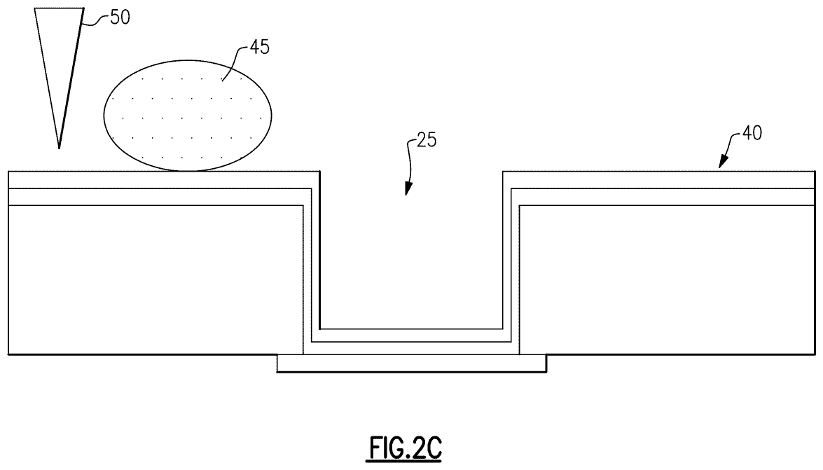

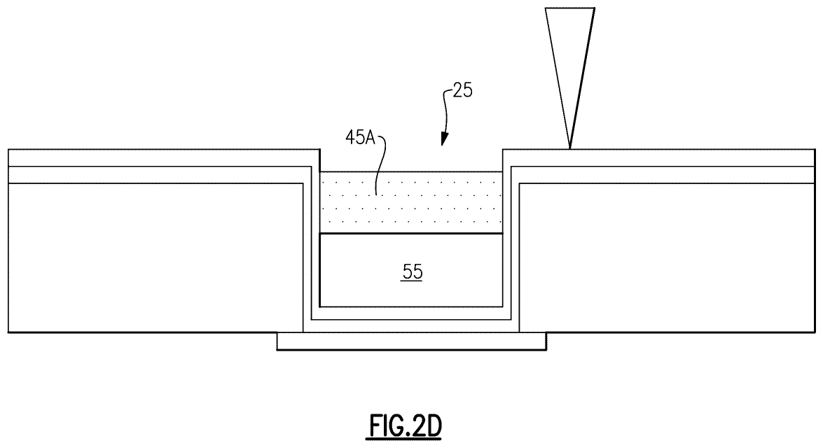

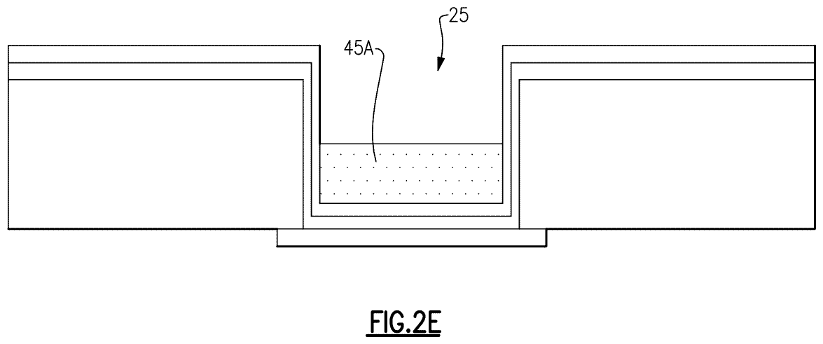

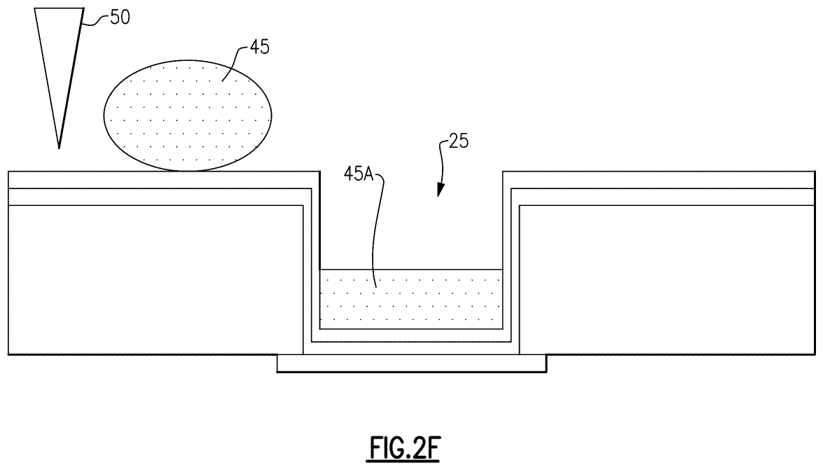

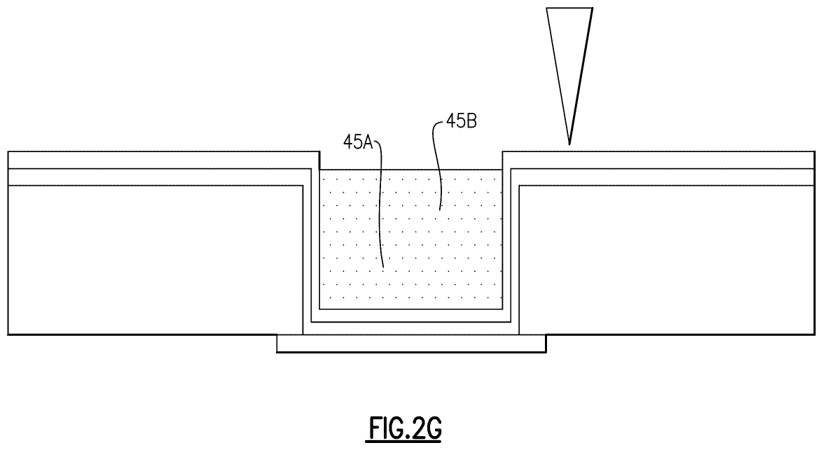

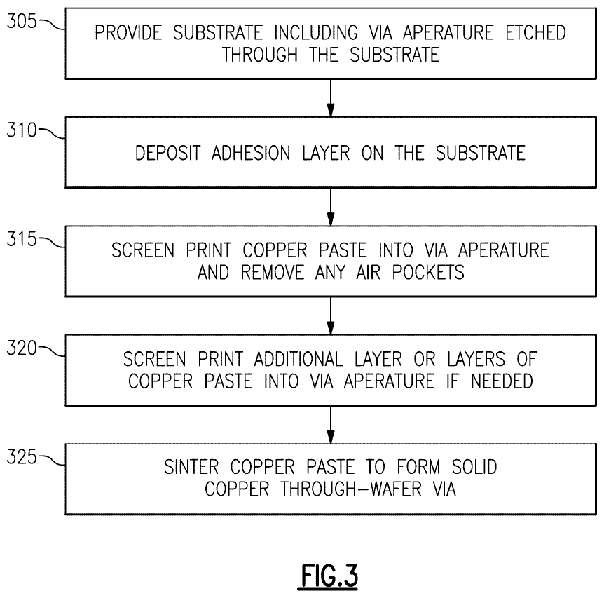

An example of a process flow for fabricating copper TWVs in accordance with the present disclosure is illustrated in FIGS. 2A-2G and in the corresponding flowchart in FIG. 3.

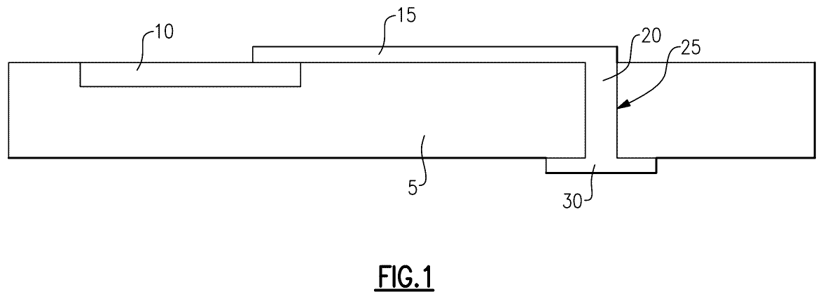

In act 305 illustrated in FIG. 2A, a substrate 5 is provided and an aperture or via hole 25 is etched through the substrate where the TWV is to be formed. The substrate may be a semiconductor such as Si, Ge, GaAs, InN or any other semiconductor material, a dielectric such as SiO₂ or sapphire, a piezoelectric material such as lithium niobate or lithium tantalate, or any other material useful as a substrate for forming electronic devices. Etching of the aperture 25 may be performed with an anisotropic etch such as by plasma etching with a gas selected based on the material of the substrate 5, ion milling, laser drilling, or even by mechanically drilling. In certain embodiments a front metal layer 35 may be utilized. The front metal layer 35 may be formed of a metal selected based on the material of the substrate and form of etching or chemicals used to etch the aperture 25 and may function as an etch stop layer for etching the aperture 25. The front metal layer 35 may be used for an electrical contact such as the electrical contact 30 illustrated in FIG. 1.

In act 310 illustrated in FIG. 2B an adhesion layer 40 is deposited on the substrate 5, including on the walls of the aperture 25 and the upper surface of the front metal layer 35. The adhesion layer 40 may be formed of Ti, a TiW alloy, or a multi-layer adhesion layer 40 including a lower layer 40A of TiW alloy and an upper layer 40B of Cu. The adhesion layer 40 may be deposited by chemical vapor deposition (CVD), sputtering, or by evaporation deposition. The lower layer 40A of TiW alloy may also function as a barrier layer. The upper layer 40B of Cu may function as a seed layer upon which copper paste is subsequently deposited.

In act 315 shown in FIG. 2C, Cu paste 45 is applied to the top of the adhesion/barrier/seed layer 40 and a squeegee 50 is used to move the Cu paste 45 into the aperture 25, at least partially filling the aperture with a first layer 45A of the Cu paste 45, as illustrated in FIG. 2D.

As also shown in FIG. 2D, an air pocket 55 may be trapped in the aperture 25 below the first layer 45A of the Cu paste 45. This air pocket 55 may be removed by subjecting the illustrated structure to a vacuum to result in the configuration shown in FIG. 2E. In some embodiments, the front metal layer 35 may be at least partially air or gas permeable so that air or gas forming the air pocket 55 may pass outward through the front metal layer 35.

In act 320 shown in FIG. 2F additional Cu paste 45 is applied to the top of the adhesion layer 40 and moved into the aperture 25 by the squeegee 50 to fill the aperture 25 with a second screen-printed layer 45B of the Cu paste on top of the first layer 45A of the Cu paste 45 as shown in FIG. 2G. There may be no discernable demarcation between the first layer 45A and second layer 45B of the Cu paste. It should be appreciated that apertures with a lower aspect ratio may be completely filled with only a single screen printing step.

The substrate 5 including the filled via aperture 25 is then sintered (act 325) to solidify the Cu paste 45 into a solid Cu via 20 such as is illustrated in FIG. 1.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method of forming a through wafer via in a substrate, the method comprising:
defining an aperture in the substrate, the aperture defining one of a through hole passing entirely through the substrate from a front side of the substrate to a rear side of the substrate or a blind hole terminating on a metal pad disposed on the rear side of the substrate;
depositing a copper paste within the aperture; and
sintering the copper paste.

2. The method of claim 1 wherein defining the aperture in the substrate includes etching the substrate.

3. The method of claim 2 wherein defining the aperture in the substrate includes performing an anisotropic etch on the substrate.

4. The method of claim 2 wherein defining the aperture in the substrate includes performing an isotropic etch on the substrate.

5. The method of claim 2 wherein defining the aperture in the substrate includes plasma etching the substrate.

6. The method of claim 1 wherein defining the aperture in the substrate includes performing an ion milling operation on the substrate.

7. The method of claim 1 further comprising disposing an etch stop layer on the rear side of the substrate prior to defining the aperture above the etch stop layer.

8. The method of claim 1 wherein depositing the copper paste within the aperture includes screen printing the copper paste into the aperture.

9. The method of claim 1 wherein screen printing the copper paste into the aperture includes partially filling the aperture with copper paste by screen printing a first layer of copper paste into the aperture.

10. The method of claim 9 further comprising screen printing a second layer of the copper paste on top of the first layer of copper paste, the first and second layer of copper paste filling the aperture.

11. The method of claim 9 further comprising removing an air pocket from the aperture below the first layer of copper paste.

12. The method of claim 11 wherein removing the air pocket includes exposing the rear side of the substrate to a vacuum.

13. The method of claim 1 further comprising depositing an adhesion layer on walls of the aperture prior to depositing the copper paste within the aperture.

14. The method of claim 13 where the adhesion layer is deposited by sputtering.
